(19) United States
(12) Patent Application Publication
(10) Pub. No.: US 2022/0120814 A1
(43) Pub. Date: Apr. 21, 2022

(54) Battery Storage And Testing Assembly

(71) Applicant: David Greenlee, Columbia, TN (US)

(72) Inventor: David Greenlee, Columbia, TN (US)

(21) Appl. No.: 17/072,191

(22) Filed: Oct. 16, 2020

(51) Int. Cl. G01R 31/36; B07C 5/344

(52) U.S. Cl. CPC G01R 31/3646; B07C 5/344

(57) ABSTRACT

A battery storage and testing assembly for storing and testing a variety of disposable batteries includes a plurality of chutes that each has unique dimensions with respect to each other to store respective sizes of disposable batteries. The plurality of chutes is removably attachable together thereby enhancing convenience of accessing the disposable batteries. A battery tester is provided and the battery tester is attached to a respective one of the chutes. The battery tester has a test port coupled thereto to electrically engage a battery for testing the charge of the battery.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to storage devices and more particularly pertains to a new storage device for storing a testing a variety of types of disposable batteries.

### (2) Description of Related Art Including Information Disclosed Under 37 CFR 1.97 and 1.98

The prior art relates to storage devices including a variety of storage devices for storing wafer type batteries. The prior art discloses a variety of storing and charging methods for storing and charging batteries. The prior art also discloses a battery storage device that includes a plurality of channels for containing a variety of disposable batteries.

### BRIEF SUMMARY OF THE INVENTION

An embodiment of the disclosure meets the needs presented above by generally comprising a plurality of chutes that each has unique dimensions with respect to each other to store respective sizes of disposable batteries. The plurality of chutes is removably attachable together thereby enhancing convenience of accessing the disposable batteries. A battery tester is provided and the battery tester is attached to a respective one of the chutes. The battery tester has a test port coupled thereto to electrically engage a battery for testing the charge of the battery.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front perspective view of a battery storage and testing assembly according to an embodiment of the disclosure.

FIG. 2 is an exploded perspective view of an embodiment of the disclosure.

FIG. 3 is a back phantom view of an embodiment of the disclosure.

FIG. 4 is a perspective in-use view of an embodiment of the disclosure.

FIG. 5 is a cross sectional view taken along line 5-5 of FIG. 4 of an embodiment of the disclosure.

### DETAILED DESCRIPTION OF THE INVENTION

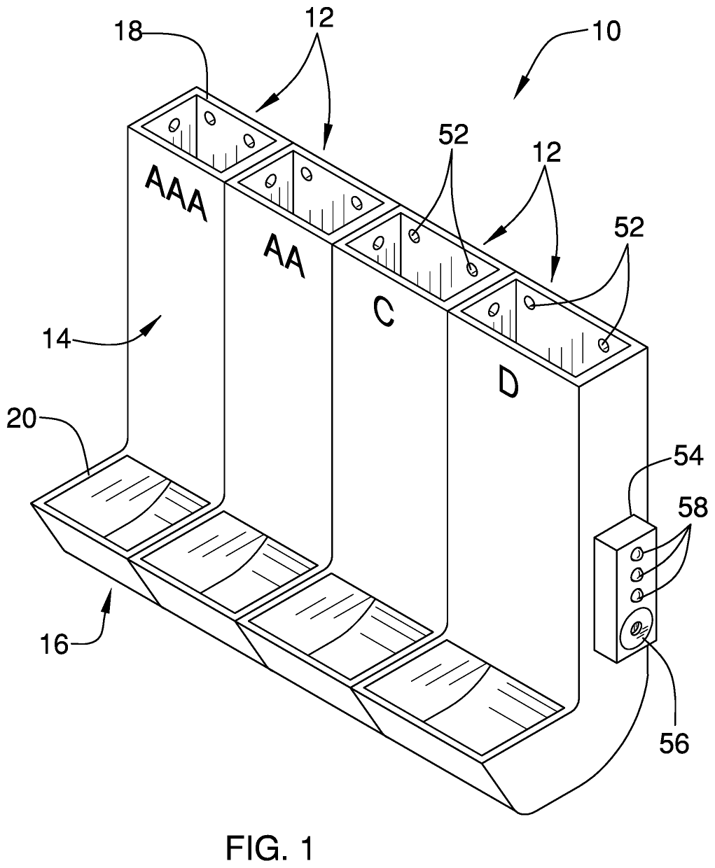

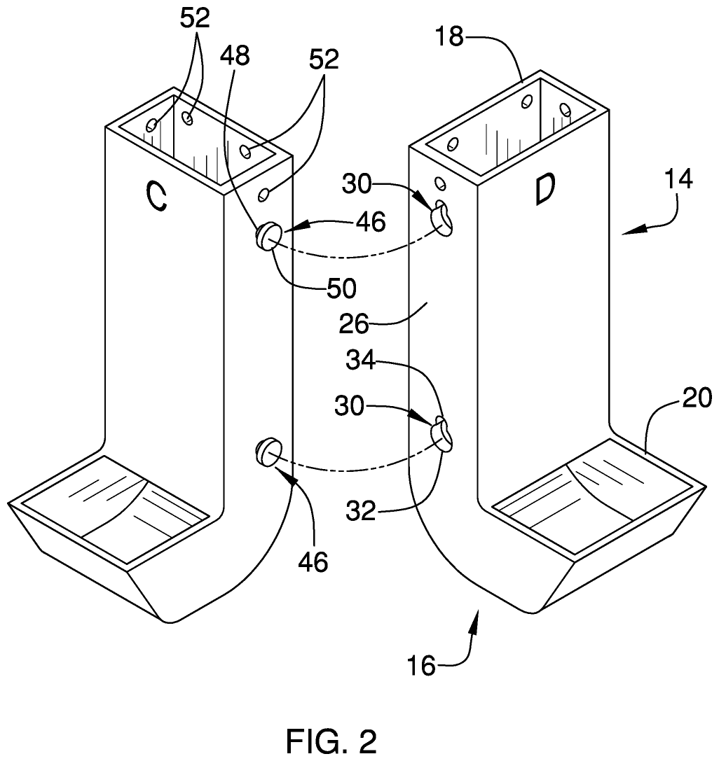

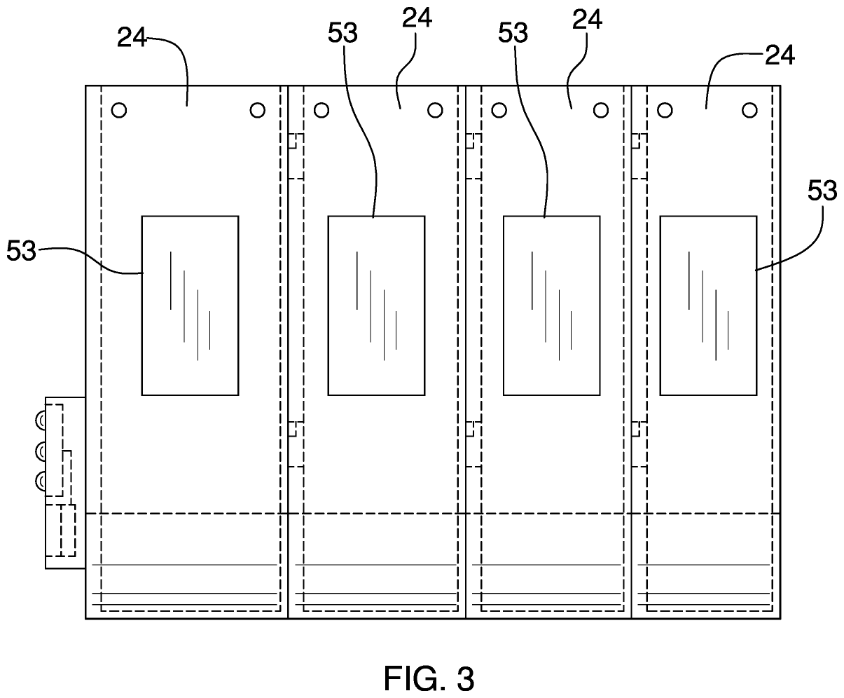

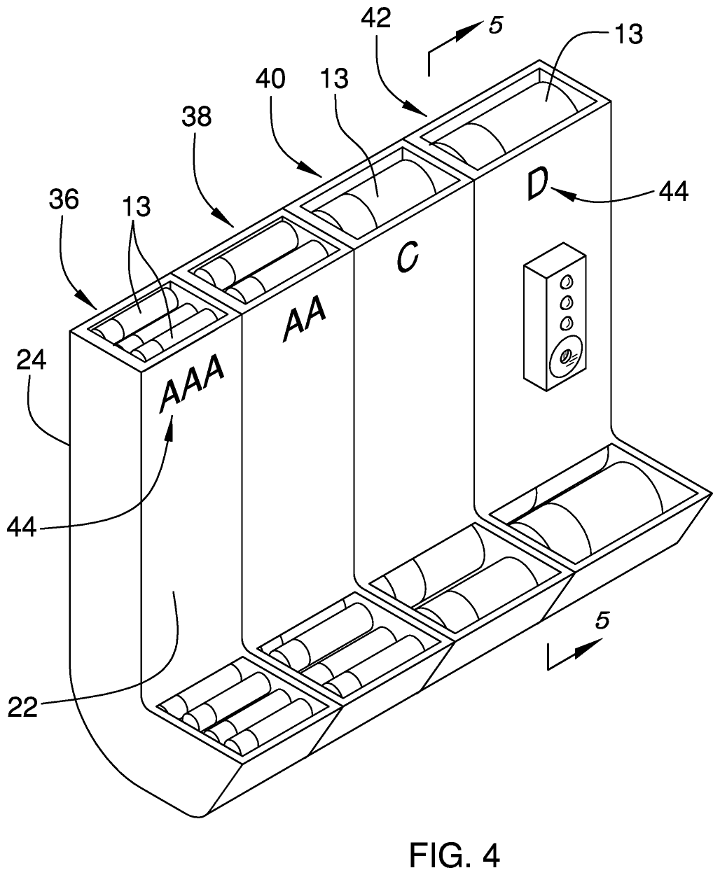

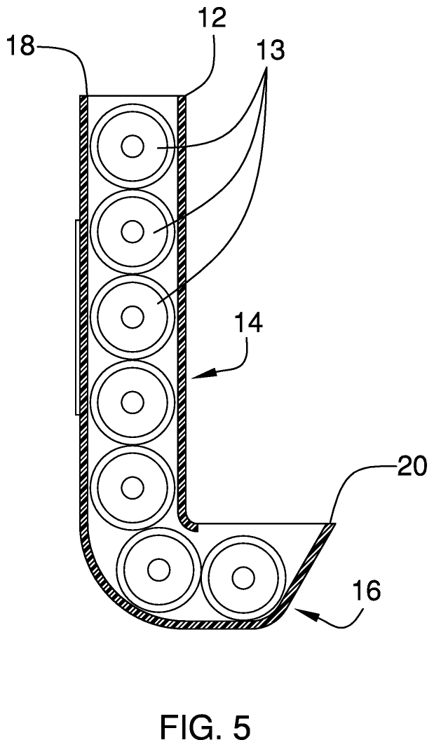

With reference now to the drawings, and in particular to FIGS. 1 through 5 thereof, a new storage device embodying the principles and concepts of an embodiment of the disclosure and generally designated by the reference numeral 10 will be described.

As best illustrated in FIGS. 1 through 5, the battery storage and testing assembly 10 generally comprises a plurality of chutes 12 that each has unique dimensions with respect to each other. In this way each of the chutes 12 can store respective sizes of disposable batteries 13. The plurality of chutes 12 is removably attachable together thereby enhancing convenience of accessing the disposable batteries 13. Each of the chutes 12 has leg 14 and a foot 16, the leg 14 has a top end 18 and the top end 18 is open to receive the disposable batteries 13. The foot 16 has a top side 20 and the top side 20 is open to dispense the disposable batteries 13.

The leg 14 has a front wall 22, a back wall 24, a first lateral wall 26 and a second lateral wall 28, the first lateral wall 26 of the leg 14 has a pair of openings 30 each extending therethrough, and each of the openings 30 has a lower portion 32 that has a diameter which is greater than a diameter of the top portion 34. The openings 30 are spaced apart from each other and are distributed between the top end 18 and the foot 16.

The plurality of chutes 12 includes a first chute 36, a second chute 38, a third chute 40 and a fourth chute 42. Each of the first chute 36, the second chute 38, the third chute 40 and the fourth chute 42 has a unique width with respect to each other. The front wall 22 of the leg 14 of each of the chutes 12 has indicia 44 printed thereon. The indicia 44 on the first chute 36 comprise the letters “AAA” to indicate that AAA cell batteries are positionable in the first chute 36. The indicia 44 on the second chute 38 comprise the letters “AA” to indicate that AA cell batteries are positionable in the second chute 38. The indicia 44 on the third chute 40 comprise the letter “C” to indicate that C cell batteries are positionable in the third chute 40. The indicia 44 on the fourth chute 42 comprise the letter “D” to indicate that D cell batteries are positionable in the fourth chute 42.

A plurality of engagements 46 is provided and each of the engagements 46 is coupled to the second lateral wall 28 of the leg 14 of a respective one of the chutes 12. The engagements 46 are spaced apart from each other and are distributed between the top end 18 of the leg 14 and the foot 16 of the respective chute. Each of the engagements 46 comprises a stem 48 and a head 50. The stem 48 extends outwardly from the second lateral wall 28 has the head 50 being spaced from the second lateral wall 28. The head 50 is extendable through the lower portion 32 of a respective one of the openings 30 in the first lateral wall 26 of the leg 14 of a respective one of the chutes 12. Additionally, the stem 48 is slidable upwardly into the upper portion of the respective opening for attaching the plurality of chutes 12 together.

Each of the first lateral wall 26, the back wall 24 and the second lateral wall 28 of the leg 14 of each of the chutes 12 has a respective one of a plurality of holes 52 extending therethrough. Each of the holes 52 is positioned adjacent to the top end 18 of the leg 14 of a respective chute 12. Fasteners, such as nails or screws, can be extended through respective holes to mounting the chutes 12 to a wall or the like. A plurality of mating members 53 is each coupled to the back wall 24 of the leg 14 or a respective one of the chutes 12. Each of the mating members 53 engages a support surface, such as a wall or the like, for attaching the chutes 12 to the support surface. Each of the mating members 53 may comprise a magnet, a hook and loop fastener, an adhesive strip or other type of mating member.

A battery tester 54 is provided and the battery tester 54 is attached to a respective one of the chutes 12. The battery tester 54 has a test port 56 coupled thereto to electrically engage a disposable battery 13 for testing the charge of the battery. The battery tester 54 includes a plurality of indicators 58 that is coupled the battery tester 54 and the indicators 58 are vertically distributed on the battery tester 54. The indicators 58 are sequentially turned on along the vertical distribution when the battery tester 54 tests a disposable battery 13. In this way the indicators 58 can indicate a charge of the disposable battery 13 ranging between a minimum charge and a maximum charge.

In use, AAA cell batteries, AA cell batteries, C cell batteries and D cell batteries are positionable into respective chutes 12 for storage. Thus, a chosen number of the various disposable batteries 13 can be drawn outwardly from the chutes 12. Additionally, the disposable batteries 13 can be tested on the battery tester 54 prior to being used. In this way a person that regularly uses batteries 13 can store the various disposable batteries 13 in an organized and easily accessible manner. Each of the chutes 12 can be refilled with the respective various batteries 13 as needed.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A battery storage and testing assembly for storing and testing a variety of types of batteries, said assembly comprising:
a plurality of chutes each having unique dimensions with respect to each other wherein each of said chutes is configured to store respective sizes of disposable batteries, said plurality of chutes being removably attachable together thereby enhancing convenience of accessing the disposable batteries; and
a battery tester being attached to a respective one of said chutes, said battery tester having a test port coupled thereto wherein said test port is configured to electrically engage a battery for testing the charge of the battery.

2. The assembly according to claim 1, wherein each of said chutes has a leg and a foot, said leg having a top end and said foot having a top side, said top end being open wherein said top end is configured to receive the disposable batteries, said top side being open wherein said top side of configured to dispense the disposable batteries.

3. The assembly according to claim 2, wherein said leg has a front wall, a back wall, a first lateral wall and a second lateral wall, said first lateral wall of said leg having a pair of openings each extending therethrough, each of said openings having a lower portion having a diameter being greater than a diameter of a top portion, said openings being spaced apart from each other and being distributed between said top end and said foot.

4. The assembly according to claim 3, wherein said plurality of chutes including a first chute, a second chute, a third chute and a fourth chute, each of said first chute, said second chute, said third chute and said fourth chute having a unique width with respect to each other.

5. The assembly according to claim 3, wherein:
said front wall of said leg of each of said chutes having indicia being printed thereon; and
said plurality of chutes includes a first chute, a second chute, a third chute and a fourth chute.

6. The assembly according to claim 5, wherein said indicia on said first chute comprises the letters “AAA” wherein said indicia on said first chute is configured to indicate that AAA cell batteries are positionable in said first chute.

7. The assembly according to claim 5, wherein said indicia on said second chute comprises the letters “AA” wherein said indicia on said second chute is configured to indicate that AA cell batteries are positionable in said second chute.

8. The assembly according to claim 5, wherein said indicia on said third chute comprises the letter “C” wherein said indicia on said third chute is configured to indicate that C cell batteries are positionable in said third chute.

9. The assembly according to claim 5, wherein said indicia on said fourth chute comprises the letter “D” wherein said indicia on said fourth chute is configured to indicate that D cell batteries are positionable in said fourth chute.

10. The assembly according to claim 3, further comprising a plurality of engagements, each of said engagements being coupled to said second lateral wall of said leg of a respective one of said chutes, said engagements being spaced apart from each other and being distributed between said top end of said leg and said foot of said respective chute.

11. The assembly according to claim 6, wherein each of said engagements comprises a stem and a head, said stem extending outwardly from said second lateral wall having said head being spaced from said second lateral wall, said head being extendable through said lower portion of a respective one of said openings in said first lateral wall of said leg of a respective one of said chutes, said stem being slidable upwardly into said upper portion of said respective opening for attaching said plurality of chutes together.

12. The assembly according to claim 3, wherein each of said first lateral wall, said back wall and said second lateral wall of said leg of each of said chutes having a respective one of a plurality of holes extending therethrough, each of said holes being positioned adjacent to said top end of said leg of a respective chute.

13. A battery storage and testing assembly for storing and testing a variety of types of batteries, said assembly comprising:
a plurality of chutes each having unique dimensions with respect to each other wherein each of said chutes is configured to store respective sizes of disposable batteries, said plurality of chutes being removably attachable together thereby enhancing convenience of accessing the disposable batteries, each of said chutes having leg and a foot, said leg having a top end and said foot having a top side, said top end being open wherein said top end is configured to receive the disposable batteries, said top side being open wherein said top side of configured to dispense the disposable batteries, said leg having a front wall, a back wall, a first lateral wall and a second lateral wall, said first lateral wall of said leg having a pair of openings each extending therethrough, each of said openings having a lower portion having a diameter being greater than a diameter of a top portion, said openings being spaced apart from each other and being distributed between said top end and said foot, said plurality of chutes including a first chute, a second chute, a third chute and a fourth chute, each of said first chute, said second chute, said third chute and said fourth chute having a unique width with respect to each other, said front wall of said leg of each of said chutes having indicia being printed thereon, said indicia on said first chute comprising the letters “AAA” wherein said indicia on said first chute is configured to indicate that AAA cell batteries are positionable in said first chute, said indicia on said second chute comprising the letters “AA” wherein said indicia on said second chute is configured to indicate that AA cell batteries are positionable in said second chute, said indicia on said third chute comprising the letter “C” wherein said indicia on said third chute is configured to indicate that C cell batteries are positionable in said third chute, said indicia on said fourth chute comprising the letter “D” wherein said indicia on said fourth chute is configured to indicate that D cell batteries are positionable in said fourth chute;
a plurality of engagements, each of said engagements being coupled to said second lateral wall of said leg of a respective one of said chutes, said engagements being spaced apart from each other and being distributed between said top end of said leg and said foot of said respective chute, each of said engagements comprising a stem and a head, said stem extending outwardly from said second lateral wall having said head being spaced from said second lateral wall, said head being extendable through said lower portion of a respective one of said openings in said first lateral wall of said leg of a respective one of said chutes, said stem being slidable upwardly into said upper portion of said respective opening for attaching said plurality of chutes together, each of said first lateral wall, said back wall and said second lateral wall of said leg of each of said chutes having a respective one of a plurality of holes extending therethrough, each of said holes being positioned adjacent to said top end of said leg of a respective chute; and
a battery tester being attached to a respective one of said chutes, said battery tester having a test port coupled thereto wherein said test port is configured to electrically engage a battery for testing the charge of the battery, said battery tester including a plurality of indicators being coupled thereto, said indicators being vertically distributed on said battery tester, said indicators being sequentially turned on along said vertical distribution when said battery tester tests a battery wherein said indicators is configured to indicate a charge of the battery ranging between a minimum charge and a maximum charge.
